(19) United States
(12) Patent Application Publication
(10) Pub. No.: US 2017/0114465 A1
(43) Pub. Date: Apr. 27, 2017

(54) Methods Of Depositing Flowable Films Comprising SiO and SiN

(71) Applicant: Applied Materials, Inc., Santa Clara, CA (US)

(72) Inventors: Lakmal Kalutarage, San Jose, CA (US); Mark Saly, Santa Clara, CA (US); David Thompson, San Jose, CA (US)

(21) Appl. No.: 15/297,262

(22) Filed: Oct. 19, 2016

Related U.S. Application Data
(60) Provisional application No. 62/244,791, filed on Oct. 22, 2015.

(51) Int. Cl. C23C 16/50; H01J 37/32; C23C 16/34; C23C 16/56; H01L 21/02; C23C 16/40

(52) U.S. Cl. CPC C23C 16/50; H01L 21/02271; H01L 21/02164; H01L 21/0217; H01L 21/02216; H01L 21/02222; H01L 21/02348; H01L 21/0214; C23C 16/401; C23C 16/345; C23C 16/56; H01J 37/32357; H01J 2237/3321

(57) ABSTRACT

Provided are methods for depositing flowable films comprising SiO or SiN. Certain methods comprise exposing a substrate surface to a siloxane or silazane precursor; exposing the substrate surface to a plasma-activated co-reactant to provide a SiON intermediate film; UV curing the SiON intermediate film to provide a cured intermediate film; and annealing the cured intermediate film to provide a film comprising SiO or SiN.

### CROSS-REFERENCE TO RELATED APPLICATIONS

This application claims priority to U.S. Provisional Application No. 62/244,791, filed Oct. 22, 2015, the entire disclosure of which is hereby incorporated by reference herein.

### TECHNICAL FIELD

The present invention relates generally to methods of depositing thin films. In particular, the invention relates to flowable chemical vapor deposition of Si-containing films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization benefits from a high level control of thin film deposition to produce conformal coatings on high aspect structures. One method for deposition of thin films with relative control and conformal deposition is chemical vapor deposition (CVD). CVD involves exposing a substrate (e.g., a wafer) to one or more precursors, which react to deposit a film onto the substrate. Flowable chemical vapor deposition (FCVD) is a type of CVD that allows for the deposition of flowable films, in particular for gap fill applications.

SiO and SiN flowable films are utilized for gap fill applications. Currently, such films are generated by trisilylamine (TSA) with radical forms of NH3/O2 as co-reactants. The SiO films have a wet etch rate ratio (WER) of 3. However, a WER of less than 2 is generally targeted for gap fill applications. The as-deposited films obtained from the TSA process comprise Si and N as major components, with O as a minor component.

There is a need for new deposition chemistries that are commercially viable and exhibit both flowable properties as well as low WERRs. Aspects of the present invention address this problem by providing novel chemistries which are specifically designed and optimized to take advantage of the deposition process. There is especially a need for new chemistries for the deposition of flowable films comprising SiO and SiN.

### SUMMARY

One aspect of the invention pertains to a method of depositing a film comprising SiO or SiN, the method comprising exposing a substrate surface to a siloxane or silazane precursor; exposing the substrate surface to a plasma-activated co-reactant to provide a SiON intermediate film; UV curing the SiON intermediate film to provide a cured intermediate film; and annealing the cured intermediate film to provide a film comprising SiO or SiN.

Another aspect of the invention pertains to a method of depositing a film comprising SiO, the method comprising exposing a substrate surface to a siloxane precursor comprising disiloxane; exposing the substrate surface to a remote plasma-activated NH3 to provide a SiON intermediate film; UV curing the SiON intermediate film in the presence of ozone to provide a cured intermediate film; and steam annealing the cured intermediate film to provide a film comprising SiO.

Another aspect of the invention pertains to a method of depositing a film comprising SiN, the method comprising exposing a substrate surface to a silazane precursor comprising N,N′-disilyltrisilazane; exposing the substrate surface to a remote plasma-activated NH3 and/or O2 to provide a SiON intermediate film; UV curing the SiON intermediate film to provide a cured intermediate film; and NH₃ annealing the cured intermediate film to provide a film comprising SiN.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is the FTIR spectra of a film deposited in accordance with one or more embodiments of the invention;

FIG. 2 is the FTIR spectra of a film deposited in accordance with one or more embodiments of the invention and after four days of aging;

FIG. 3 is a comparison of the FTIR spectra of a film deposited in accordance with one or more embodiments of the invention and a comparative film;

FIG. 4 is the FTIR spectra of a film deposited in accordance with one or more embodiments of the invention;

FIG. 5 is the FTIR spectra of a film deposited in accordance with one or more embodiments of the invention after 10 days of aging;

FIG. 6 is the FTIR spectra of a film deposited in accordance with one or more embodiments of the invention after steam annealing;

FIG. 7 is a graph of the wet etch ratio and shrinkage of a film deposited according to one or more embodiments of the invention;

FIGS. 8A-D are scanning electron microscope images of films deposited in accordance with one or more embodiments of the invention at various conditions;

FIG. 9 is the FTIR spectra of two films deposited in accordance with one or more embodiments of the invention;

FIG. 10 is a comparison of the FTIR spectra of a film deposited in accordance with one or more embodiments of the invention and a comparative film;

FIG. 11 is a comparison of the FTIR spectra of a film deposited in accordance with one or more embodiments of the invention and a comparative film;

FIG. 12 is a comparison of the FTIR spectra of a comparative film as-deposited and after four days aging;

FIG. 13 is a comparison of the FTIR spectra of a film deposited in accordance with one or more embodiments of the invention as-deposited and after four days aging;

FIG. 14 is a scanning electron microscope image of a film deposited in accordance with one or more embodiments of the invention;

FIGS. 15A-C are graphs showing the in-trench compositions of a film deposited in accordance with one or more embodiments of the invention and a comparative film; and

FIGS. 16A-C are graphs showing the in-trench compositions of a film deposited in accordance with one or more embodiments of the invention and a comparative film.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways. The illustrated structures are intended to encompass all such complexes and ligands having the indicated chemical formula.

It has been surprisingly discovered that high quality flowable films can be obtained using siloxane or silazane precursors in a flowable chemical vapor (FCVD) process. These precursors are used with co-reactants in the form of radicals generated from plasmas. The films have the advantageous effect of low WERR and low shrinkage rates. The results are particularly surprising for embodiments utilizing disiloxane, given the very high reactivity of disiloxane. Due to the superior characteristics of these films, the films are particularly suitable for gap-fill applications. In particular, the flowability of the films allows filling of the gaps.

In one or more embodiments, siloxane or silazane precursor is vaporized to a CVD chamber, and co-reactants (e.g., NH₃ only or NH₃/O₂ with or without Ar) are delivered to the chamber through a remote plasma source, which will generate plasma active species as the co-reactants. Plasma-activated co-reactant molecules (radicals) have high energies and react with Si-containing precursor molecules in the gas phase to form flowable SiON polymers. These polymers deposit on the wafer and due to their flowability, the polymers will flow through trenches and make a gap-fill. Then these films are subjected to curing (e.g., O₃ and/or UV) and annealing (e.g., steam or NH₃).

In some embodiments, a direct plasma to generate flowable polymers. A siloxane or silazane precursor may then be vaporized to a CVD chamber, and co-reactants (e.g., with any combination of N₂, Ar, NH₃, O₂ or single co-reactant) are delivered to the chamber while plasma is turned on. In some embodiments, the flowable film is deposited from a direct plasma so that the vaporized silicon precursor is flowed into the process chamber and the plasma is turned on with or without a co-reactant.

Accordingly, one aspect of the invention pertains to a method of depositing a film comprising SiO or SiN. In one or more embodiments, the method comprises exposing a substrate surface to a siloxane or silazane precursor; exposing the substrate surface to a plasma-activated co-reactant to provide a SiON intermediate film; UV curing the SiON intermediate film to provide a cured intermediate film; and annealing the cured intermediate film to provide a film comprising SiO or SiN. In one or more embodiments, the method is a flowable chemical vapor deposition process.

Siloxane and silazanes are both Si-containing precursors which serve as a source of silicon and either oxygen or nitrogen. The siloxane or silazane precursors are vaporized in a chemical vapor deposition (CVD) chamber in order to expose to the substrate surface.

In some embodiments, the precursor is a siloxane precursor. The resulting films comprise SiO in embodiments where a siloxane precursor is used. As used herein, “siloxane” refers to a compound having at least one Si—O—Si functional group. In one or more embodiments, the siloxane may be branched, cyclic or linear. In some embodiments, the siloxane may have multiple Si—O—Si functional groups. In one or more embodiments, the siloxane has no other elements. For example, in one or more embodiments, the siloxane precursor is selected from formulae (I)-(IX):

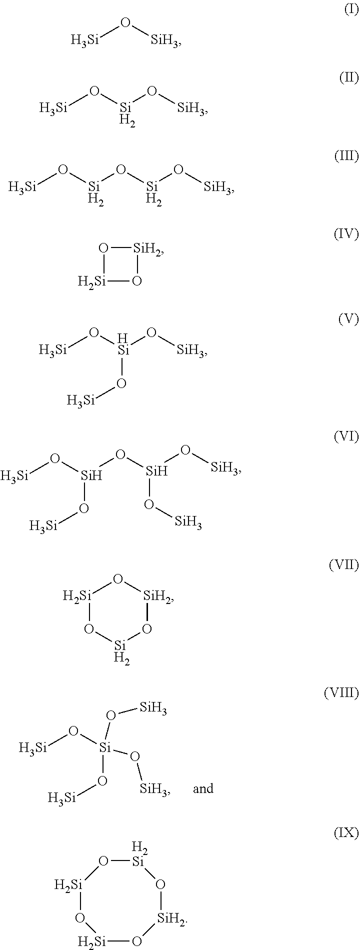

In a further embodiment, the siloxane precursor comprises disiloxane, which has the structure of formula (I).

In one or more embodiments, the precursor is a silazane precursor. The resulting films comprise SiN in embodiments where a silazane precursor is used. As used herein, “silazane” refers to a compound having at least one Si—N—Si functional group. In one or more embodiments, the siloxane may be branched, cyclic or linear. In some embodiments, the silazane may have multiple Si—N—Si functional groups. In one or more embodiments, the silazane has no other elements. For example, in some embodiments, the silazane precursor is selected from the group consisting of:

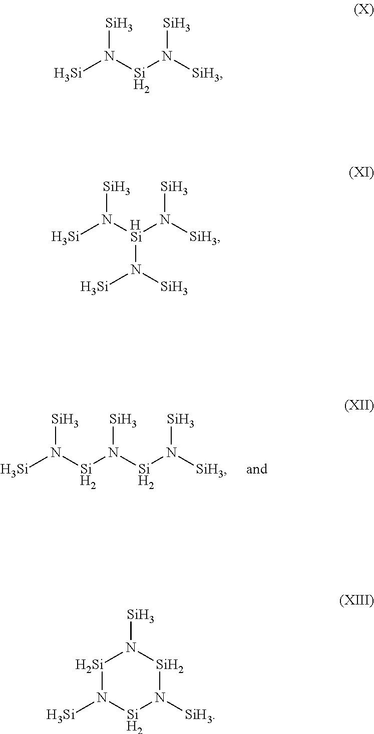

In one or more embodiments, the silazane precursor comprises N,N′-disilyltrisilazane, which has the structure of formula (X).

As discussed above, the substrate surface is exposed to a plasma-activated co-reactant. In some embodiments, the co-reactants are selected from the group consisting of NH₃, O₂ and combinations thereof. The co-reactant may also comprise one or more of Ar, He and/or N₂. The plasma-activated co-reactants will also deliver nitrogen and/or oxygen to the film, depending on the co-reactant used. In some embodiments pertaining to siloxane precursors, the co-reactant comprises NH₃. In some embodiments pertaining to silazane precursors, the co-reactant comprises a mixture of NH₃ and O₂ or NH₃ only.

In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either directly (i.e., within the processing area) or remotely (i.e., outside the processing area). In some embodiments, remote ionization can occur upstream of the deposition chamber such that ions or other energetic or light emitting species are not in direct contact with the depositing film. In some plasma-enhanced processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz.

In one or more embodiments, the co-reactants are delivered to the CVD chamber containing the vaporized siloxane or silazane precursor through a remote plasma source, which will generate plasma active species as the co-reactants. In an alternative embodiment, a direct plasma to generate flowable polymers.

In some embodiments, the substrate may be exposed to the precursor and plasma-activated co-reactant continuously simultaneously, or substantially simultaneously, as appropriate. As used herein, the term “substantially simultaneously” means that a majority of the flow of one component overlaps with the flow of another, although there may be some time where they are not co-flowed. In alternative embodiments, contacting the substrate surface with two or more precursors occurs sequentially or substantially sequentially. As used herein, “substantially sequentially” means that a majority of the flow of one component does not coincide with the flow of another, although there may be some overlap.

A “substrate” as used throughout this specification, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. The substrate may comprise node device structures (e.g., 32 nm, 22 nm or sub-20 nm), and may include transistor isolation, various integrated and sacrificial spacers, and sidewall spacer double patterning (SSDP) lithography. In one or more embodiments, the substrate comprises at least one gap. The substrate may have a plurality of gaps for the spacing and structure of device components (e.g., transistors) formed on the substrate. The gaps may have a height and width that define an aspect ratio (AR) of the height to the width (i.e., H/W) that is significantly greater than 1:1 (e.g., 5:1 or more, 6:1 or more, 7:1 or more, 8:1 or more, 9:1 or more, 10:1 or more, 11:1 or more, 12:1 or more, etc.). In many instances the high AR is due to small gap widths of that range from about 90 nm to about 22 nm or less (e.g., about 90 nm, 65 nm, 45 nm, 32 nm, 22 nm, 16 nm, etc.).

In addition to film processing directly on the surface of the substrate itself, in the present invention any of the film processing steps disclosed may also be performed on an underlayer formed on the substrate as disclosed in more detail below, and the term “substrate surface” is intended to include such underlayer as the context indicates.

In one or more embodiments of any of the above-described reactions, the reaction conditions for the deposition reaction will be selected based on the properties of the film precursors and substrate surface. The deposition may be carried out at atmospheric pressure, but may also be carried out at reduced pressure. The vapor pressure of the reagents should be low enough to be practical in such applications. The substrate temperature should be low enough to keep the bonds of the substrate surface intact and to prevent thermal decomposition of gaseous reactants. However, the substrate temperature should also be high enough to keep the film precursors in the gaseous phase and to provide sufficient energy for surface reactions. The specific temperature depends on the specific substrate, film precursors, and pressure. The properties of the specific substrate, film precursors, etc. may be evaluated using methods known in the art, allowing selection of appropriate temperature and pressure for the reaction. In some embodiments, the pressure is less than about 6.0, 5.0, 4.0, 3.0, 2.6, 2.0 or 1.6 Torr. In one or more embodiments, the deposition is carried out at a temperature less than about 200, 175, 150, 125, 100, 75° C., and/or greater than about −1, 0 23, 50 or 75° C.

The film deposited after the substrate is exposed to the siloxane or silazane precursor and plasma-activated co-reactant comprises SiON (referred to as the “SiON intermediate film”). In general, the as-deposited films are relatively low dense films with less networks and more dangling bonds such as Si—H, Si—OH, and N—H. As a result, their WERR are usually extremely high. In order to get low WERR/dense films, the film is subjected to further treatments to obtain a high density film. During these treatments remaining reactive bonds (e.g., SiH, NH) react with each other or with incoming molecules (e.g., O₃, water, NH₃) to form a film with more networks. Thus, in order to remove either oxygen or nitrogen to achieve the targeted film, then the film is subjected to additional curing and annealing processes. In the case of SiO films, nitrogen is removed during cure/annealing and O is added to the film to generate SiO film. However, one advantage of the siloxane precursors is that the as-deposited films already have more O in the film because the siloxane precursors contain Si—O. Therefore, conversion of the as-deposited film obtained from siloxane precursors to SiO is easier compared to the films obtained from standard processes (e.g. those using TSA). As a result, less amount of curing/annealing may be employed for the siloxane films, which will advantageously save wafer processing time. Similarly, SiN films obtained by silazanes have more N present in the as-deposited film than the films obtained from TSA.

In one or more embodiments, curing comprises exposing the intermediate SiON film to ozone and/or ultraviolet (UV) radiation. In further embodiments, the intermediate SiON film is exposed to ozone and UV cure to obtain a film comprising SiO. In other embodiments, the intermediate SiON film is exposed only to a UV cure to obtain a film comprising SiON.

One or more embodiments also involve an anneal process. In some embodiments, annealing comprises steam annealing. In other embodiments, annealing comprises NH₃ annealing.

Thus, for example, in one or more embodiments pertaining to a siloxane precursor (e.g., disiloxane), the SiON intermediate film is cured using ozone and UV followed by steam annealing to generate SiO film. In some embodiments pertaining to a silazane precursor (e.g., N,N′-disilyltrisilazane) is cured by UV, followed by NH₃ anneal to generate SiN film.

In one exemplary embodiment, the method comprises exposing a substrate surface to a siloxane precursor comprising disiloxane; exposing the substrate surface to a remote plasma-activated NH₃ to provide a SiON intermediate film; UV curing the SiON intermediate film in the presence of ozone to provide a cured intermediate film; and steam annealing the cured intermediate film to provide a film comprising SiO.

In further embodiments, the method is a FCVD process. In another exemplary embodiment, the method comprises exposing a substrate surface to a silazane precursor comprising N,N′-disilyltrisilazane; exposing the substrate surface to a remote plasma-activated NH₃ and/or O₂ to provide a SiON intermediate film; UV curing the SiON intermediate film to provide a cured intermediate film; and NH₃ annealing the cured intermediate film to provide a film comprising SiN.

In further embodiments, the method is a FCVD process. Another aspect of the invention pertains to films deposited by the methods described herein. The films are distinct from the flowable films previously known, as evidenced by the data presented in the Examples section below. In one or more embodiments, the deposited film has a WERR of less than about 2.

An advantage of these processes is to generate high density flowable films which have low wet etch rate and low shrinkage. Siloxanes already have Si—O bonds in the molecule which lead to Si—O bonds in the as-deposited films (with some N). Conversion of as-deposited film to SiO film may utilize less curing/annealing time and energy compared to currently known techniques. Also, the presence of SiO in the as-deposited film leads to low shrinkage with low WERR. Similarly, as-deposited films obtained from silazanes have more N, which may use less curing/annealing time and energy, and films with low shrinkage and low WERR. These films have particular utility for gap fill applications. Thus, in some embodiments, the substrate has at least one gap, and the process at least partially fills the gap.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, like a conveyer system, in which multiple substrate are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The substrate and chamber may be exposed to a purge step after stopping the flow of the precursor, co-reagent, etc. In one or more embodiments of any of the aspects described herein, a purge gas may be flowed after any of the precursors is flowed/exposed to a substrate surface. A purge gas may be administered into the processing chamber with a flow rate within a range from about 10 sccm to about 2,000 sccm, for example, from about 50 sccm to about 1,000 sccm, and in a specific example, from about 100 sccm to about 500 sccm, for example, about 200 sccm. The purge step removes any excess precursor, byproducts and other contaminants within the processing chamber. The purge step may be conducted for a time period within a range from about 0.1 seconds to about 8 seconds, for example, from about 1 second to about 5 seconds, and in a specific example, from about 4 seconds. The carrier gas, the purge gas, the deposition gas, or other process gas may contain nitrogen, hydrogen, argon, neon, helium, or combinations thereof. In one example, the carrier gas comprises nitrogen.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

### EXAMPLES

### Example 1

### SiO Deposition

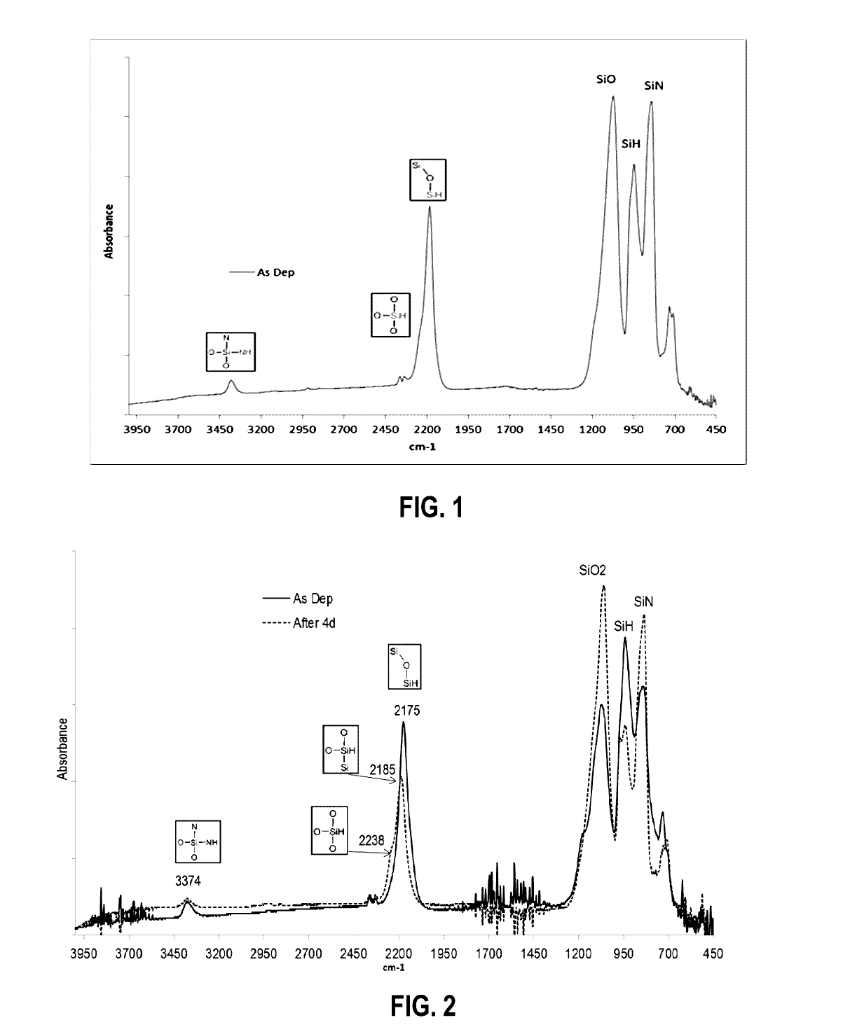

A film was deposited in accordance with one or more embodiments of the invention using disiloxane and remote plasma-activated NH₃. Disiloxane, NH₃, Ar, and He flow rates were changed from 400-500, 10-50, 400-600, 50-150 sccm, respectively. The refractive index (RI) of the as-deposited films was 1.48. FIG. 1 shows the Fourier Transform Infrared (FTIR) spectra of an exemplary deposited film. As can be seen in the figure, the SiO, SiN, SiH, and NH peaks are prominent. There are two types of SiH bond stretching, one at 2175 cm⁻¹ and a shoulder peak at 2238 cm⁻¹. The later peak originates from SiH bonds that are in a more network-like environment, while the peak at 2175 cm⁻¹ originates from SiH bonds that are in a less network-like environment. NH stretching at 3374 cm⁻¹ originates from NH bonds attached to SiON network.

### Example 2

### Aging of SiO Film

A film was deposited in accordance with one or more embodiments of the invention using disiloxane and remote plasma-activated NH₃. This film was aged four days by keeping under ambient conditions (room temperature, atmospheric pressure, under air). FIG. 2 shows the FTIR spectra of the as-deposited film, as well as after aging for four days. As can be seen from the figure, after 4 days of aging, SiH and NH peaks were reduced. Conversely, SiO and SiN peaks were increased after the four days. The shift of the SiH peak from right to left, decrease of the NH peak, increase of the SiO and SiN peaks show that the film forms more network when ages. Thus, as expected because of the presence of SiH, the films age with time, resulting films shrinkage and reduction of RI.

The refractive index (RI) and shrinkage of the film was measured, and shown in Table 1. As can be seen from the table, the shrinkage and RI of the as-deposited film changes over 4 days. The RI drops from 1.48 to 1.45, while the shrinkage increases from 2 to 6.8 during the 4 days.

TABLE 1

| Day | Refractive Index | Shrinkage (%) |
|---|---|---|
| 1 | 1.48 | 2.5 |
| 2 | 1.46 | 3 |
| 3 | 1.457 | 3.7 |
| 4 | 1.451 | 6.8 |

### Example 3

### Comparative SiO Film

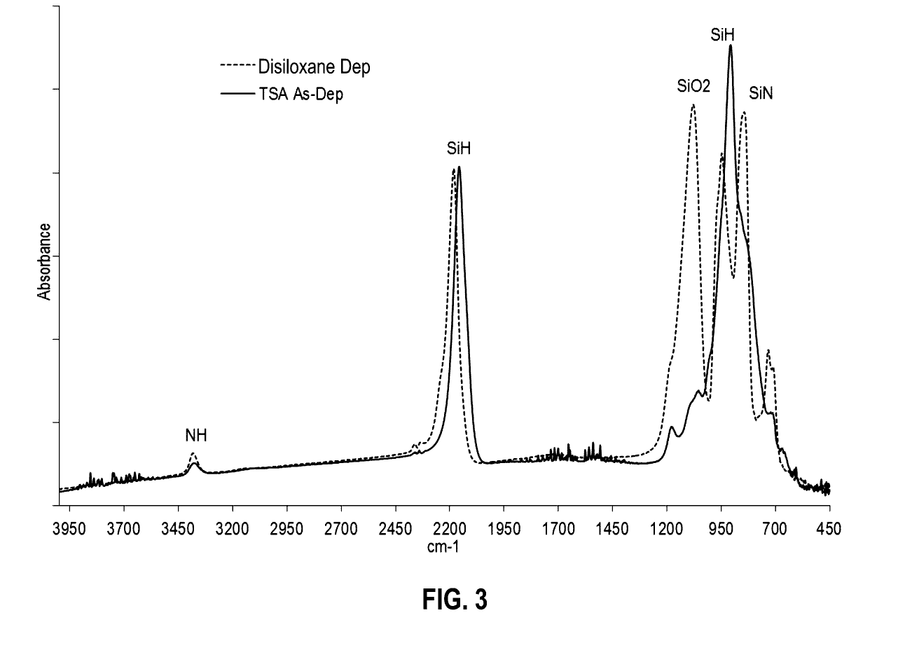

A comparative film was deposited using trimethylsilyl amine (TSA) with remote plasma-activated NH₃/O₂ (referred to as the “TSA film”). A comparison of the FTIR spectra for this film, as well as the FTIR spectra for the film of Example 1 is shown in FIG. 3. As can be seen from the figure, the as-deposited TSA film does not have prominent SiO and SiN peaks, while the inventive film has prominent SiO and SiN peaks. Also, the TSA film has very a prominent SiH peak, which means the ratio of SiO+SiN/SiH is higher in the inventive film than in the TSA film. This ratio suggests that the inventive film is more stable than TSA film because disiloxane has less SiH bonds, which are very reactive.

The as-deposited TSA film has a RI of 1.6. As discussed above, the inventive film has a RI of 1.48, which is closer to pure SiO films. This result indicates that the inventive film has characteristics more similar to pure SiO films than those deposited using TSA.

### Example 4

### Effect of Steam Anneal

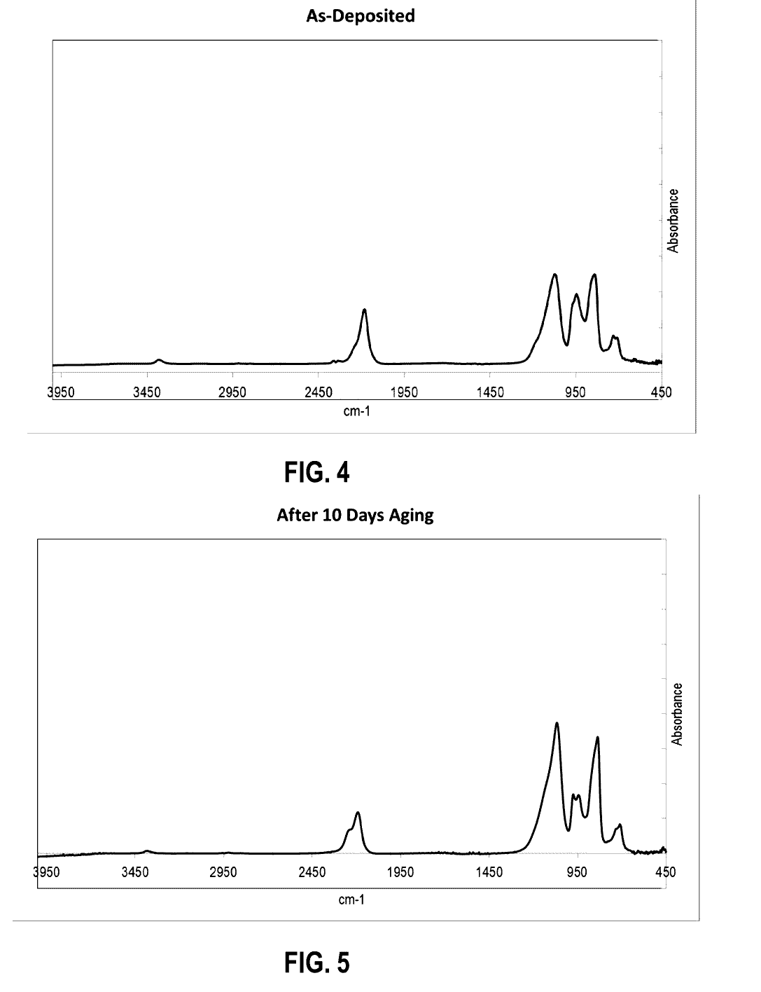

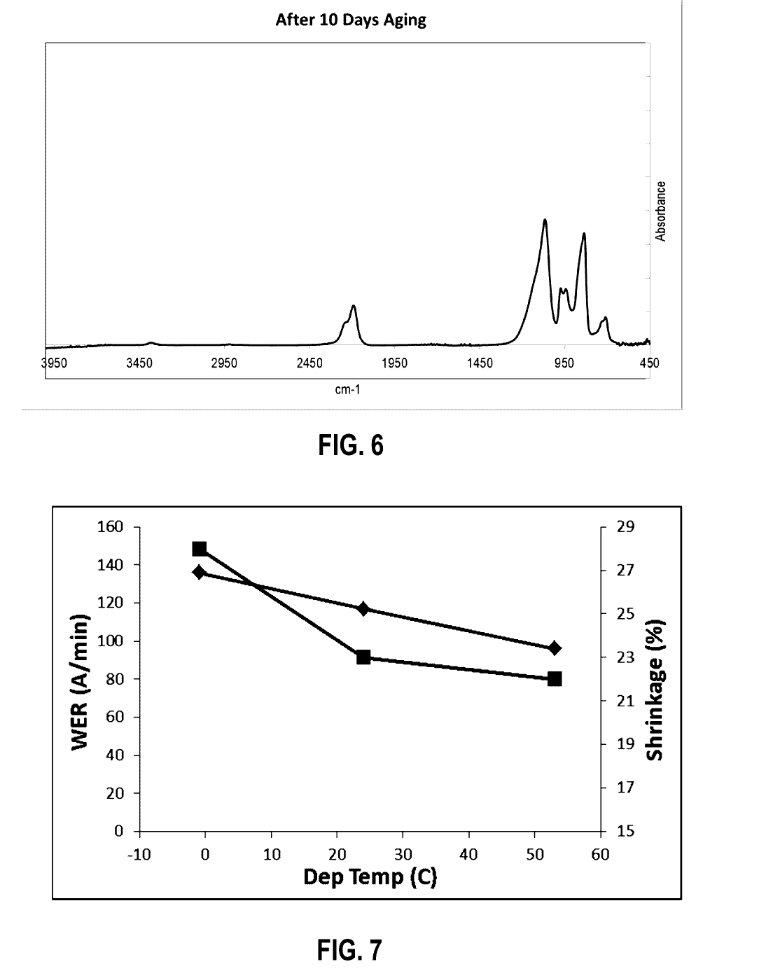

A film was deposited in accordance with one or more embodiments of the invention using disiloxane and remote plasma-activated NH₃. The FTIR of this film is shown in FIG. 4. This film was then aged for 10 days by keeping under ambient conditions (room temperature, atmospheric pressure, under air). The FTIR of the film after aging is shown in FIG. 5. The film was also steam annealed at 500° C. after the 10 days of aging. The FTIR of the film after anneal is shown in FIG. 6. As can be seen in the figures, after the steam anneal, only the peaks corresponding to pure SiO films can be seen.

Steam annealing experiments of several films according to the above were carried out to determine the WER and shrinkage of the annealed film as a function of deposition temperature. The results are summarized in FIG. 7. As shown in the figure, when the deposition temperature is higher, the WER and shrinkage are lower. These films have WERR ranging from 3.5-5 and shrinkage ranging from 22-28%.

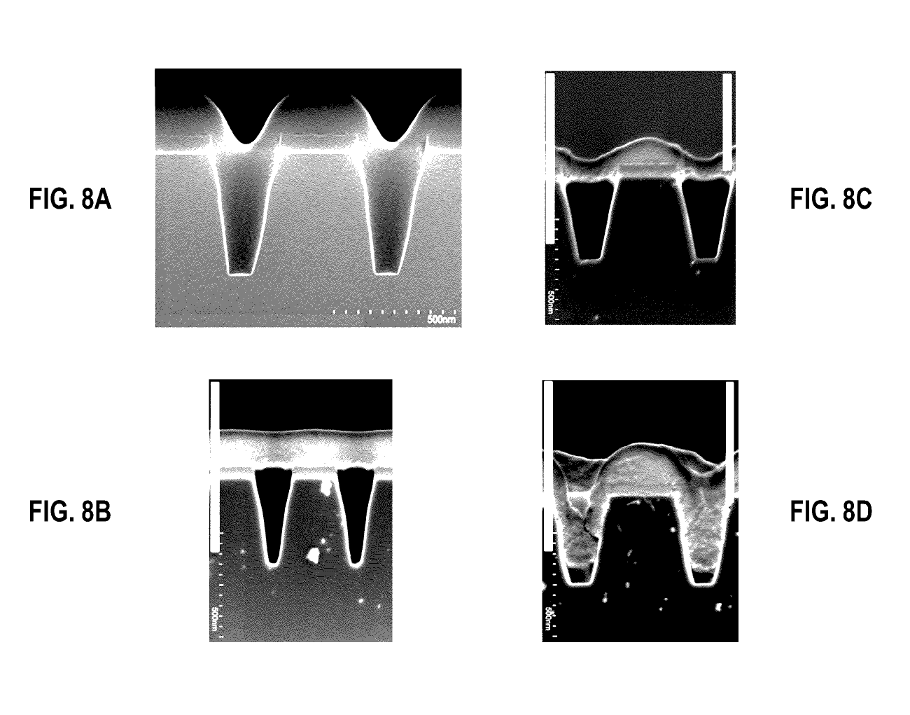

FIGS. 8A-D show scanning electron microscope (SEM) images demonstrating the effect of steam anneal and dilute hydrofluoric acid (DHF) decoration. FIG. 8A is an SEM image of a film deposited with disiloxane and remote plasma-activated NH₃ at 53° C. as-deposited without anneal or DHF dip. FIGS. 8B-D show films deposited with disiloxane and remote NH₃ plasma at −1, 24 and 53° C., respectively, after steam anneal and one minute DHF dip. As can be seen from the figures, for the film deposited at 53° C., the film in trenches has partially survived in DHF while the other films deposited at lower temperature are etched in DHF. These results suggest that higher deposition temperatures give better film qualities.

### Example 5

### SiN Deposition

Films comprising SiN were deposited using N,N′-disilyltrisilazane as the Si-containing precursor with either remote plasma-activated NH₃ or NH₃/O₂ as the reactive gas. Flowable films were deposited between 40 and −60° C. under pressures ranging from 0.9 to 1.2 Torr. N,N′-disilyltrisilazane, NH3, O2, Ar, and He flow rates were changed from 0.2-0.4 g/min, 55-85, 7-10, 560-725, 700-800 sccm, respectively. RI of the as-deposited films was 1.58.

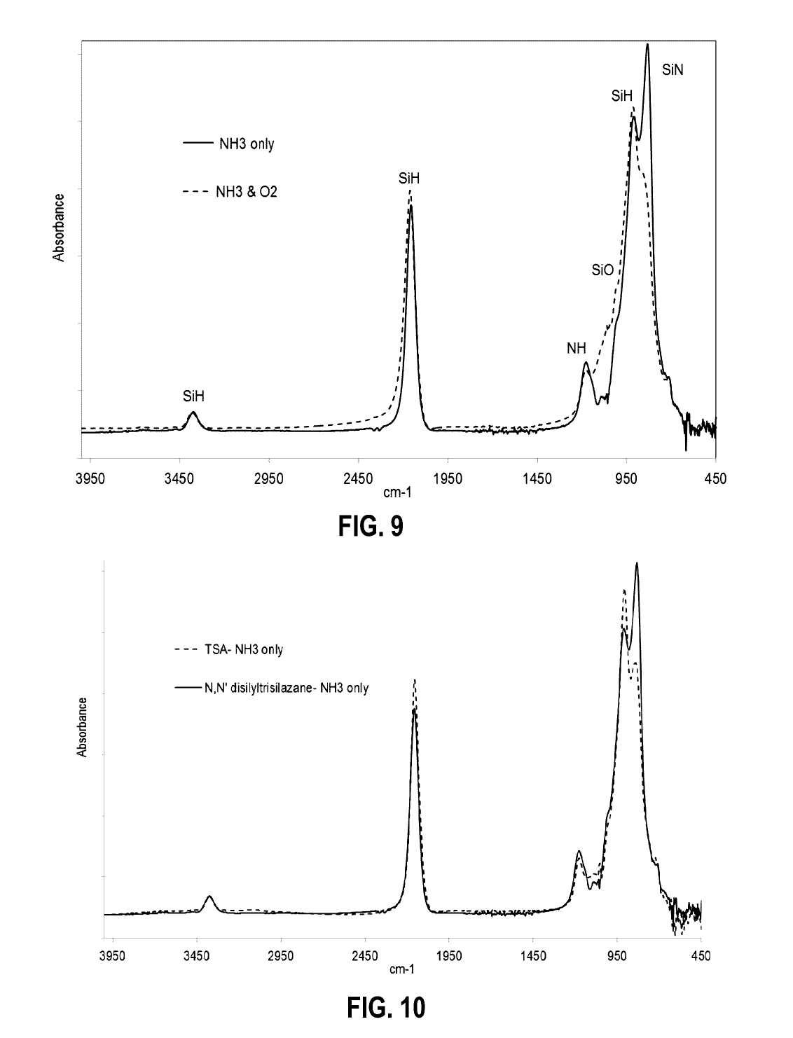

A typical FTIR of as-deposited films from remote plasma-activated NH₃ and NH₃/O₂ are shown in FIG. 9. In the FTIR of NH₃ only film, the SiN, SiH, and NH peaks are prominent, while there is a shoulder in the SiH peak at 1000 cm⁻¹ for SiO. In the NH₃/O₂ film, The SiN peak is significantly lower and the shoulder for SiO is a little higher than in NH₃ only film. Therefore, when NH₃ is used, the film has more SiN than SiO.

### Example 6

### Comparative SiN Film

A comparative film was deposited using TSA and NH₃. The NH₃ was remote plasma activated. The FTIR spectra for this film are shown in FIG. 10, along with the FTIR data for the N,N′-disilyltrisilazane/NH₃ film in Example 5. As can be seen in the figure, SiN peak intensity is higher and SiH intensity is lower for the N,N′-disilyltrisilazane film than in the TSA film. Presence of higher amounts of SiN in the film is an advantage when converting to SiN film. Lower amounts of SiH suggest that films obtained from N,N′-disilyltrisilazane are less reactive, which would lead to less shrinkage.

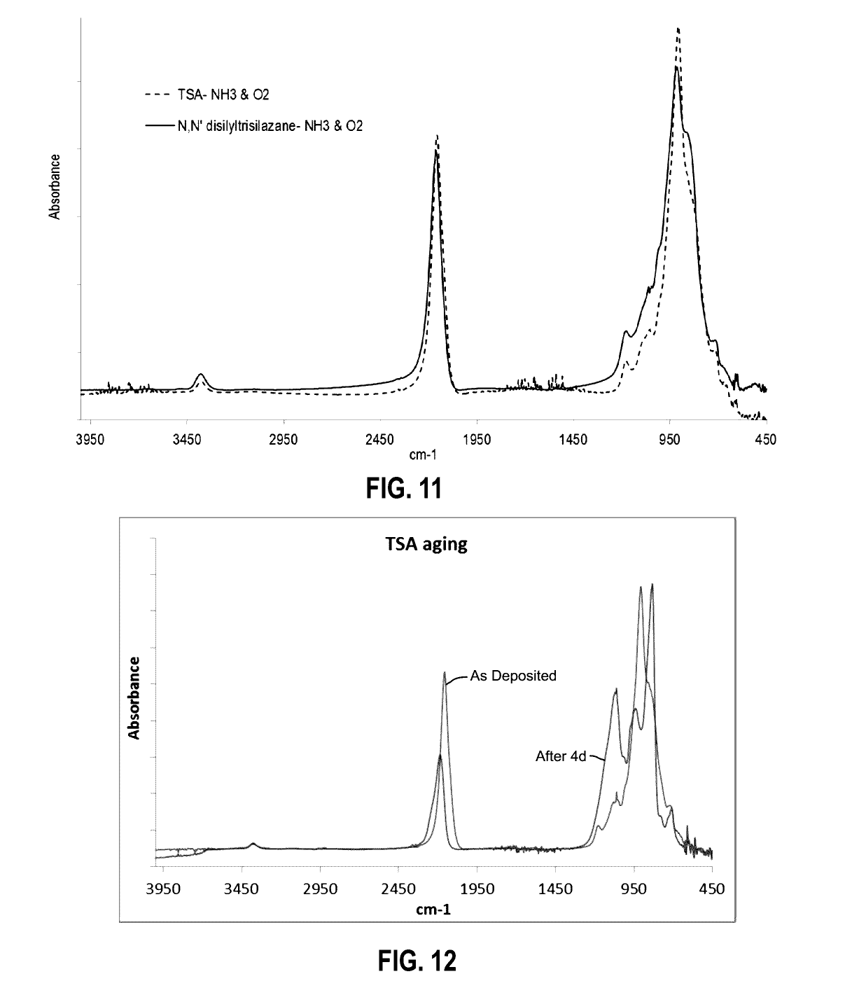

Similarly, a comparison of the FTIR of a film deposited using TSA and NH₃/O₂ and N,N′-disilyltrisilazane/NH₃/O₂ is shown in FIG. 11. These spectra show less SiH and higher SiN peak intensities of the film obtained from N,N′-disilyltrisilazane, which again demonstrate that N,N′-disilyltrisilazane is a superior precursor for SiN flowable films than TSA.

### Example 7

### Aging of SiN Film and Comparative Film

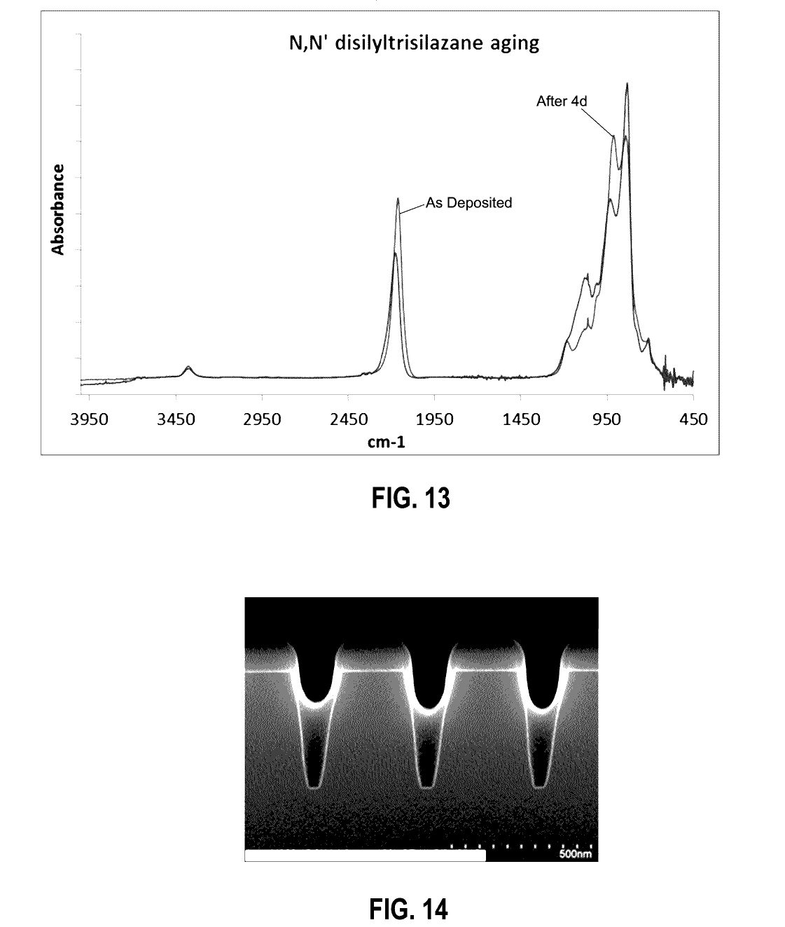

A film deposited using TSA and a remote plasma-activated NH₃/O₂ mixture was then aged for four days by keeping under ambient conditions (room temperature, atmospheric pressure, under air). The FTIR spectra of the TSA film as-deposited and after aging are shown in FIG. 12. FIG. 13 shows the FTIR data of a film deposited using N,N′-disilyltrisilazane and a plasma-activated NH₃/O₂ mixture as-deposited and after four days aging.

As can be seen from the figures, the TSA film exhibits increased SiO peak intensity during aging, when compared to N,N′-disilyltrisilazane film. These results suggest that the TSA film absorbs moisture and O₂ from the air more rapidly than the N,N′ disilyltrisilazane film. Also the reduction of SiH peak intensity is lower in N,N′-disilyltrisilazane film because the N,N′-disilyltrisilazane film is less reactive.

### Example 8

### SEM Image of SiN Film

The SEM of an as-deposited flowable film is shown in FIG. 14. The films was deposited using N,N′-disilyltrisilazane and a remote plasma-activated NH₃/O₂ mixture.

### Example 8

### Compositional Analysis of SiO and SiN Films

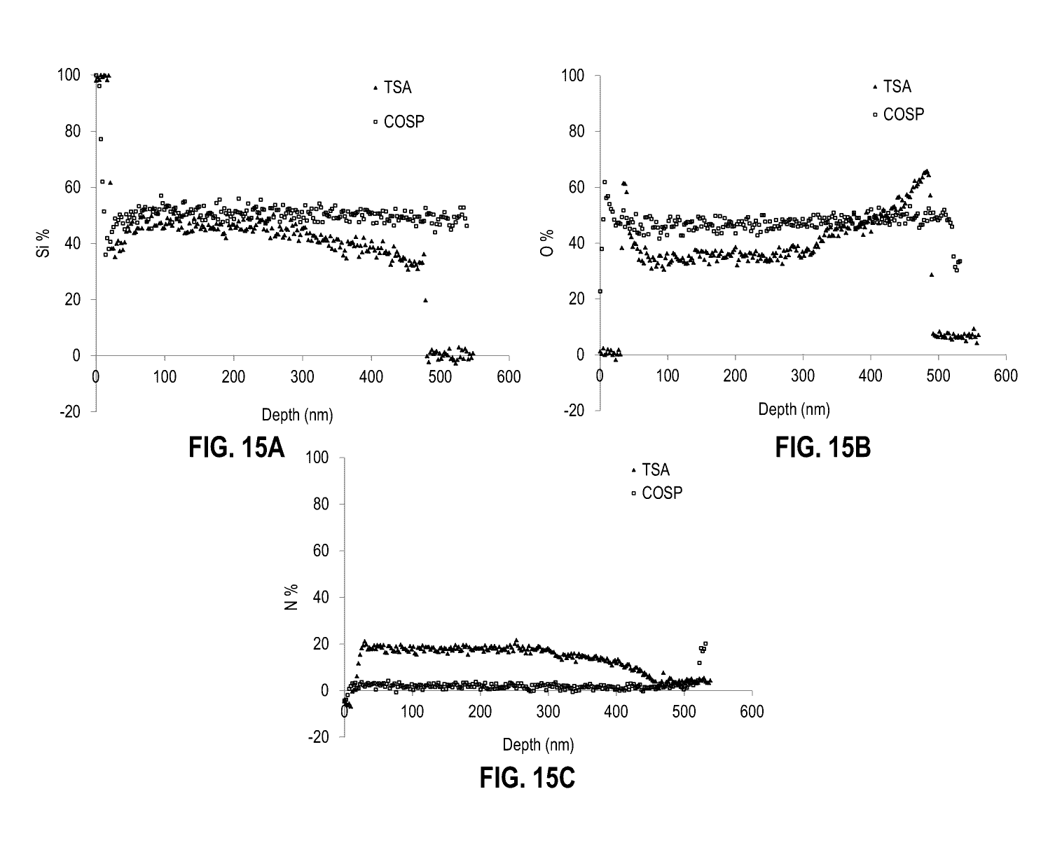

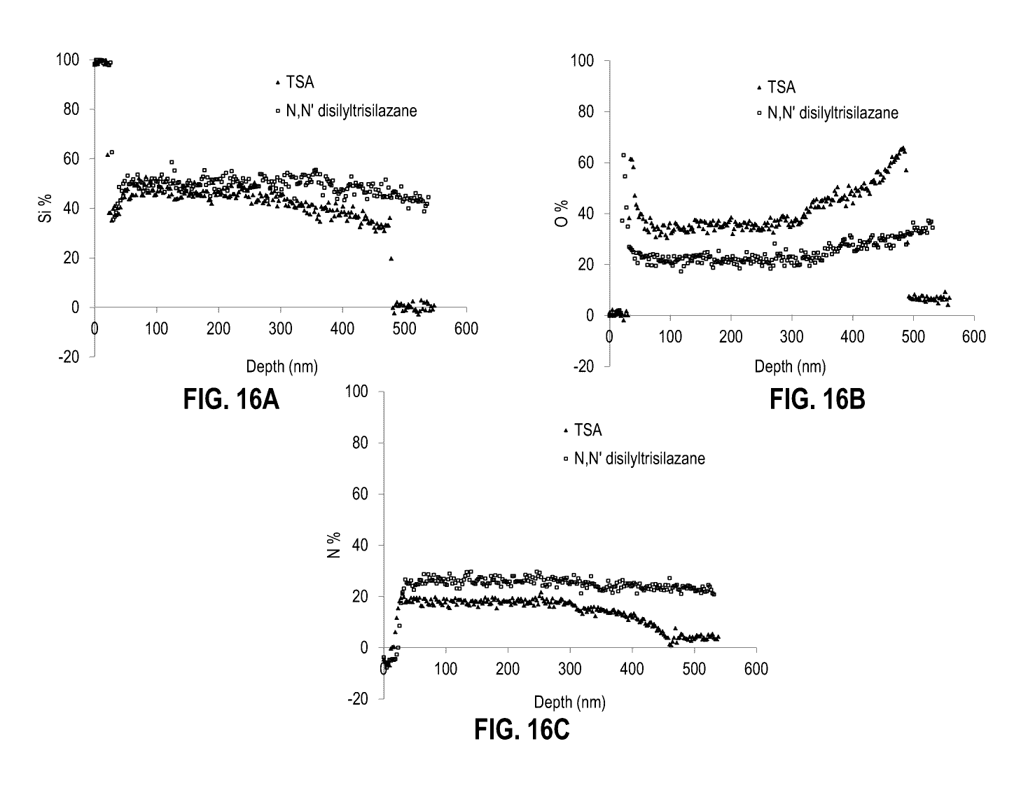

In-trench composition analyses of TSA, disiloxane, and N,N′-disilyltrisilazane films were carried out. TEM/EELS were done to analyze the in-trench composition of the films. FIGS. 15A-C show the elemental composition of a disiloxane and TSA film prepared as described above of silicon, oxygen and nitrogen, respectively. FIGS. 16A-C show the composition of N,N′-disilyltrisilazane and TSA films prepared as described above. These films were deposited as described above and then cured by ozone and UV. In the comparison of TSA film with the disiloxane film, the disiloxane film has higher Si and O contents than the TSA film. Most importantly, the N content is almost zero. Therefore, disiloxane may be a better Si precursor than TSA precursor for the deposition of flowable SiO films. Films obtained from N,N′-disilyltrisilazane have higher Si and N content compared to the films obtained from TSA. Also, O level is lower in N,N′-disilyltrisilazane films, which suggest that N,N′-disilyltrisilazane is a better candidate to deposit SiN flowable films. In both cases (disiloxane and N,N′-disilyltrisilazane), EELS results are comparable with FT-IR data of the as-deposited films.

What is claimed is:

1. A method of depositing a film comprising SiO or SiN, the method comprising
exposing a substrate surface to a siloxane or silazane precursor;
exposing the substrate surface to a plasma-activated co-reactant to provide a SiON intermediate film;
UV curing the SiON intermediate film to provide a cured intermediate film; and
annealing the cured intermediate film to provide a film comprising SiO or SiN.

2. The method of claim 1, wherein the method is a flowable chemical vapor deposition process.

3. The method of claim 1, wherein the co-reactant comprises NH₃ and/or O₂.

4. The method of claim 1, wherein the substrate surface is exposed to a siloxane precursor, and the deposited film comprises SiO.

5. The method of claim 4, wherein annealing comprises steam annealing.

6. The method of claim 4, wherein the siloxane precursor is selected from the group consisting of:

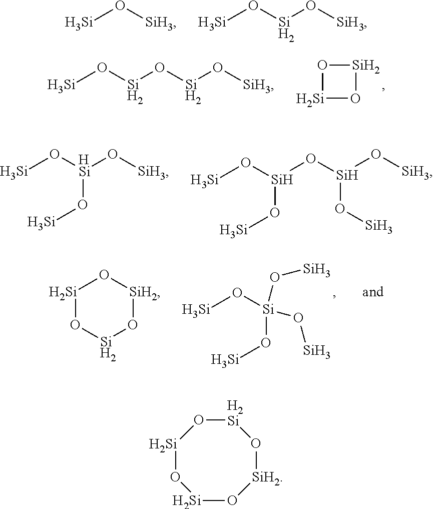

7. The method of claim 6, wherein the siloxane precursor comprises disiloxane.

8. The method of claim 1, wherein the substrate surface is exposed to a silazane precursor, and the deposited film comprises SiN.

9. The method of claim 8, wherein annealing comprises NH₃ annealing.

10. The method of claim 8, wherein the silazane precursor is selected from the group consisting of:

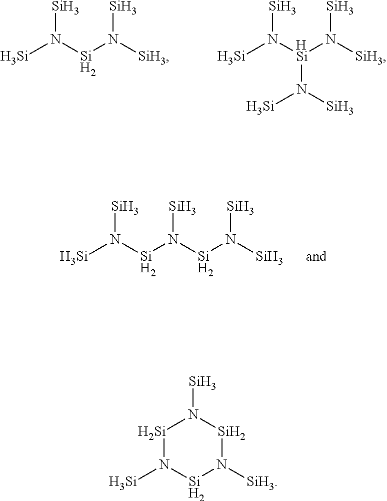

11. The method of claim 10, wherein the silazane precursor comprises N,N′-disilyltrisilazane.

12. The method of claim 1, wherein the plasma is a remote plasma.

13. A film deposited by the method of claim 4

14. The film of claim 13, wherein the film has a wet etch rate ratio of less than about 2.

15. A film deposited by the method of claim 6.

16. The film of claim 15, wherein the film has a wet etch rate ratio of less than about 2.

17. A method of depositing a film comprising SiO, the method comprising
exposing a substrate surface to a siloxane precursor comprising disiloxane;
exposing the substrate surface to a remote plasma-activated NH₃ to provide a SiON intermediate film;
UV curing the SiON intermediate film in the presence of ozone to provide a cured intermediate film; and
steam annealing the cured intermediate film to provide a film comprising SiO.

18. The method of claim 17, wherein the method is a flowable chemical vapor deposition process.

19. A method of depositing a film comprising SiN, the method comprising
exposing a substrate surface to a silazane precursor comprising N,N′-disilyltrisilazane;
exposing the substrate surface to a remote plasma-activated NH3 and/or O2 to provide a SiON intermediate film;
UV curing the SiON intermediate film to provide a cured intermediate film; and
NH₃ annealing the cured intermediate film to provide a film comprising SiN.

20. The method of claim 19, wherein the method is a flowable chemical vapor deposition process.
